(19) United States
(12) Patent Application Publication
(10) Pub. No.: US 2020/0403179 A1
(43) Pub. Date: Dec. 24, 2020

(54) OLED DISPLAY PANEL AND OLED DISPLAY DEVICE

(71) Applicant: WUHAN CHINA STAR OPTOELECTRONICS SEMICONDUCTOR DISPLAY TECHNOLOGY CO., LTD, Wuhan, Hubei (CN)

(72) Inventors: Kai HU, Wuhan, Hubei (CN); Cuiyu HAO, Wuhan, Hubei (CN); Boyu SU, Wuhan, Hubei (CN); Li HE, Wuhan, Hubei (CN); Congcong ZHANG, Wuhan, Hubei (CN)

(21) Appl. No.: 16/612,433

(22) PCT Filed: Sep. 23, 2019
(86) PCT No.: PCT/CN2019/107169

§ 371 Date: Nov. 11, 2019

(30) Foreign Application Priority Data
Jun. 20, 2019 (CN) 201910534560.8

(51) Int. Cl. H01L 51/52; H01L 51/00; H01L 27/32

(52) U.S. Cl. CPC H01L 51/5253; H01L 27/3248; H01L 51/0097

(57) ABSTRACT

An organic light-emitting diode (OLED) display panel and an OLED display device are provided. The OLED display panel, by providing an auxiliary water-oxygen barrier layer between the light-emitting functional layer and the substrate, water-oxygen can be isolated by the auxiliary water-oxygen barrier layer even through the gap between the second flexible layer and the second flexible layer and the second barrier layer, thus preventing erosion of the light-emitting functional layer and improving the water-oxygen isolation capacity of the OLED display panels. The technical problem that current active-matrix organic light-emitting diode (AMOLED) display panels, having a poor ability to isolate water-oxygen, is solved.

### FIELD OF INVENTION

The present application relates to a field of display technologies, and in particular, to an organic light-emitting diode (OLED) display panel and an OLED display device.

### BACKGROUND OF INVENTION

As shown in FIG. 1, current active-matrix organic light-emitting diode (AMOLED) display panels are encapsulated by inorganic material and organic material; however, in the actual practices, water-oxygen enters through a second flexible layer and a gap between the second flexible layer and a second barrier layer, and then enters a luminescent material layer through an organic flexible material layer and a planarization layer. Thereby, water-oxygen affects the luminescent material layer and a pixel electrode layer, reducing lifetime of the AMOLED display panels.

Therefore, current AMOLED display panels have a technical problem of poor water-oxygen isolation capability.

### Technical Problem

The present application provides an organic light-emitting diode (OLED) display panel and an OLED display device for solving the technical problem that current AMOLED display panels have poor ability to isolate water-oxygen.

### SUMMARY OF INVENTION

To solve the above problems, the technical solution provided by the present application is as follows.

The present application provides an organic light-emitting diode (OLED) display panel, the OLED display panel including: a substrate; a driving circuit layer disposed in close contact with the substrate, the driving circuit layer includes a first via corresponding to a bending area of the driving circuit layer, and a flexible material layer provided in the first via; a planarization layer disposed on the driving circuit layer in a direction away from the substrate; a light-emitting functional layer disposed on the planarization layer in a direction away from the driving circuit layer; and an auxiliary water-oxygen barrier layer disposed between the light-emitting functional layer and the substrate.

In an OLED display panel provided by the present application, the auxiliary water-oxygen barrier layer is disposed between the substrate and the flexible material layer.

In an OLED display device provided by the present application, the auxiliary water-oxygen barrier layer is disposed around the flexible material layer and is provided with an opening in the flexible material layer in a direction away from the substrate.

In an OLED display device provided by the present application, the auxiliary water-oxygen barrier layer is disposed in the bending area, and the auxiliary water-oxygen barrier layer extends from sides of the opening to an edge of a display area of the OLED display panel and an edge of the OLED display panel.

In an OLED display device provided by the present application, the auxiliary water-oxygen barrier layer is disposed on the display area and the bending area, and the auxiliary water-oxygen barrier layer extends from sides of the opening to the edge of the display area and the edge of the OLED display panel, the auxiliary water-oxygen barrier layer is provided with a second via corresponding to the display area, and the second via is for a source/drain electrode of the driving circuit layer to pass through.

In an OLED display device provided by the present application, the driving circuit layer includes a buffer layer and a first gate insulation layer, a step of the flexible material layer is provided at an interface corresponding to the first gate insulation layer and the buffer layer, and sides of the auxiliary water-oxygen barrier layer extend to the step.

In an OLED display device provided by the present application, the auxiliary water-oxygen barrier layer includes a first auxiliary water-oxygen barrier layer and a second auxiliary water-oxygen barrier layer, the first auxiliary water-oxygen barrier layer is disposed between the flexible material layer and the substrate, the second auxiliary water-oxygen barrier layer is disposed between the light-emitting functional layer and the planarization layer and spans from the display area to the bending area, and the second auxiliary water-oxygen barrier layer is provided with a third via in the corresponding display area, and the third via is for a pixel electrode of the light-emitting functional layer to pass through.

In an OLED display device provided by the present application, the planarization layer is provided with a fourth via, the second auxiliary water-oxygen barrier layer is connected to the fourth via through the first auxiliary water-oxygen barrier layer.

In an OLED display device provided by the present application, the auxiliary water-oxygen barrier layer further includes a third auxiliary water-oxygen barrier layer, the third auxiliary water-oxygen barrier layer is disposed between the flexible material layer and a second metal layers of the driving circuit layer, and the third auxiliary water-oxygen barrier layer is connected to the first auxiliary water-oxygen barrier layer.

In an OLED display device provided by the present application, the auxiliary water-oxygen barrier layer is made of at least one of silicon oxide, silicon nitride, and silicon oxynitride.

In the meantime, the present application provides an OLED display device, the OLED display device includes an OLED display panel, the OLED display panel including a substrate; a driving circuit layer disposed in close contact with the substrate, the driving circuit layer includes a first via corresponding to a bending area of the driving circuit layer, and a flexible material layer provided in the first via; a planarization layer disposed on the driving circuit layer in a direction away from the substrate; a light-emitting functional layer disposed on the planarization layer in a direction away from the driving circuit layer; and an auxiliary water-oxygen barrier layer disposed between the light-emitting functional layer and the substrate.

In an OLED display device provided by the present application, the auxiliary water-oxygen barrier layer is disposed between the substrate and the flexible material layer.

In an OLED display device provided by the present application, the auxiliary water-oxygen barrier layer is disposed around the flexible material layer and is provided with an opening in the flexible material layer in a direction away from the substrate.

In an OLED display device provided by the present application, the auxiliary water-oxygen barrier layer is disposed in the bending area, and the auxiliary water-oxygen barrier layer extends from sides of the opening to an edge of a display area of the OLED display panel and an edge of the OLED display panel.

In an OLED display device provided by the present application, the auxiliary water-oxygen barrier layer is disposed on the display area and the bending area, and the auxiliary water-oxygen barrier layer extends from sides of the opening to the edge of the display area and the edge of the OLED display panel, the auxiliary water-oxygen barrier layer is provided with a second via corresponding to the display area, and the second via is for a source/drain electrode of the driving circuit layer to pass through.

In an OLED display device provided by the present application, the driving circuit layer includes a buffer layer and a first gate insulation layer, a step of the flexible material layer is provided at an interface corresponding to the first gate insulation layer and the buffer layer, and sides of the auxiliary water-oxygen barrier layer extend to the step.

In an OLED display device provided by the present application, the auxiliary water-oxygen barrier layer includes a first auxiliary water-oxygen barrier layer and a second auxiliary water-oxygen barrier layer, the first auxiliary water-oxygen barrier layer is disposed between the flexible material layer and the substrate, the second auxiliary water-oxygen barrier layer is disposed between the light-emitting functional layer and the planarization layer and spans from the display area to the bending area, and the second auxiliary water-oxygen barrier layer is provided with a third via in the corresponding display area, and the third via is for a pixel electrode of the light-emitting functional layer to pass through.

In an OLED display device provided by the present application, the planarization layer is provided with a fourth via, the second auxiliary water-oxygen barrier layer is connected to the fourth via through the first auxiliary water-oxygen barrier layer.

In an OLED display device provided by the present application, the auxiliary water-oxygen barrier layer further includes a third auxiliary water-oxygen barrier layer, the third auxiliary water-oxygen barrier layer is disposed between the flexible material layer and a second metal layers of the driving circuit layer, and the third auxiliary water-oxygen barrier layer is connected to the first auxiliary water-oxygen barrier layer.

In an OLED display device provided by the present application, the auxiliary water-oxygen barrier layer is made of at least one of silicon oxide, silicon nitride, and silicon oxynitride.

Beneficial Effect

The present application provides an OLED display panel and an OLED display device. The OLED display panel including a substrate, a driving circuit layer, a planarization layer, and a light-emitting functional layer, wherein the driving circuit layer is disposed in close contact with the substrate and the driving circuit layer providing a first via in a corresponding bending area, a flexible material layer is disposed in the first via, the planarization layer is disposed on the driving circuit layer in a direction away from the substrate, and a light-emitting functional layer is disposed on the planarization layer in a direction away from the driving circuit layer; wherein an auxiliary water-oxygen barrier layer is disposed between the light-emitting functional layer and the substrate. By providing an auxiliary water-oxygen barrier layer between the light-emitting functional layer and the substrate, water-oxygen can be isolated by the auxiliary water-oxygen barrier layer even through the gap between the second flexible layer and the second flexible layer and the second barrier layer, thus preventing erosion of the light-emitting functional layer and improving the water-oxygen isolation capacity of the OLED display panels. The technical problem that current active-matrix organic light-emitting diode (AMOLED) display panels, having a poor ability to isolate water-oxygen, is solved.

### BRIEF DESCRIPTION OF FIGURES

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art can obtain the other drawings without any creative effort.

FIG. 1 is a schematic view of a conventional active-matrix organic light-emitting diode (AMOLED) display panel.

FIG. 2 is a first schematic diagram of an organic light-emitting diode (OLED) display panel according to an embodiment of the present disclosure.

FIG. 3 is a second schematic diagram of the OLED display panel according to an embodiment of the present disclosure.

FIG. 4 is a third schematic diagram of the OLED display panel according to an embodiment of the present disclosure.

FIG. 5 is a fourth schematic diagram of the OLED display panel according to an embodiment of the present disclosure.

FIG. 6 is a fifth schematic diagram of the OLED display panel according to an embodiment of the present disclosure.

FIG. 7 is a sixth schematic diagram of the OLED display panel according to an embodiment of the present disclosure.

FIG. 8 is a flowchart of a method for fabricating the OLED display panel according to an embodiment of the present application.

### DETAILED DESCRIPTION OF EMBODIMENTS

The following description of each embodiment, with reference to the accompanying drawings, is used to exemplify specific embodiments which can be carried out in the present invention. Directional terms mentioned in the present invention, such as “top”, “bottom”, “front”, “back”, “left”, “right”, “inside”, “outside”, “side”, etc., are only used with reference to the orientation of the accompanying drawings. Therefore, the used directional terms are intended to illustrate, but not to limit, the present invention. In the drawings, components having similar structures are denoted by the same numerals.

The present application is intended to address technical problem of current active-matrix organic light-emitting diode (AMOLED) display panels having poor ability to isolate water-oxygen.

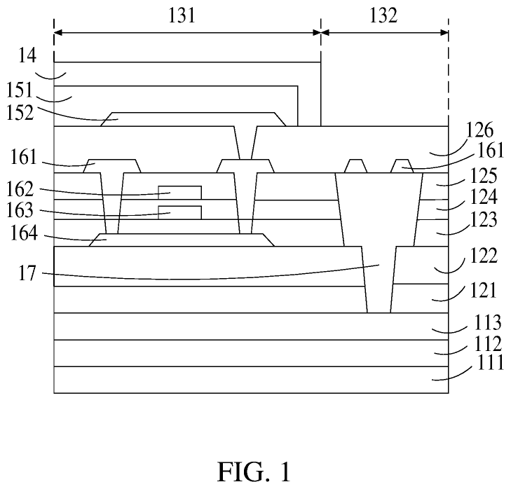

As shown in FIG. 1, one of current AMOLED display panels includes a first flexible layer 111, a first barrier layer 112, a second flexible layer 113, a second barrier layer 121, a buffer layer 122, an active layer 164, a first gate insulation layer 123, a first metal layer 163, a second gate insulation layer 124, a second metal layer 162, an interlayer insulation layer 125, a source/drain layer 161, a planarization layer 126, a pixel electrode layer 152, a luminescent material layer 151, and an encapsulation layer 14. The AMOLED display panel includes a display area 131 and a non-display area 132. The non-display area 132 is provided with an organic flexible material layer 17, in an actual process, the water-oxygen enters through the second flexible layer 113 and a gap between the second flexible layer 113 and the second barrier layer 121, and then the water-oxygen enters the luminescent material layer through the organic flexible material layer 17 and the planarization layer 126 sequentially, thereby oxidizing the luminescent material layer and the pixel electrode layer. It has an effect and reduces the lifetime of the AMOLED display panels, that is, current AMOLED display panels have a technical problem of poor water-oxygen isolation capability.

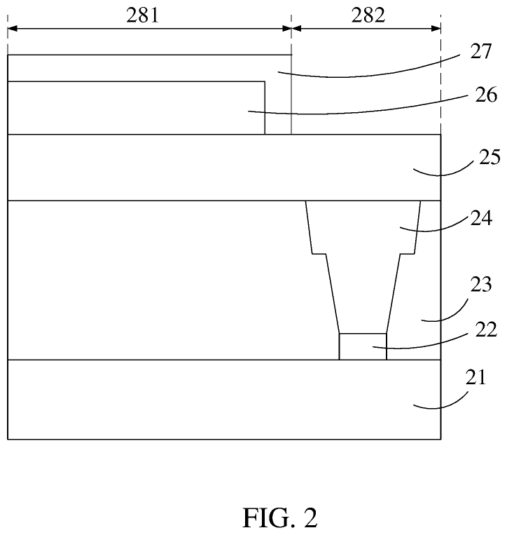

As shown in FIG. 2, an embodiment of the present application provides an organic light-emitting diode (OLED) display panel, the OLED display panel including:

a substrate 21;

a driving circuit layer 23 disposed in close contact with the substrate 21, the driving circuit layer includes a first via 23 corresponding to a bending area 282 of the driving circuit layer, and a flexible material layer 24 provided in the first via;

a planarization layer 25 disposed on the driving circuit layer 23 in a direction away from the substrate 21; and

a light-emitting functional layer 26 disposed on the planarization layer 25 in a direction away from the driving circuit layer 23;

wherein an auxiliary water-oxygen barrier layer 26 is disposed between the light-emitting functional layer 26 and the substrate 21.

An embodiment of the present application provides an OLED display panel, the OLED display panel including a substrate, a driving circuit layer, a planarization layer, and a light-emitting functional layer, wherein the driving circuit layer is disposed in close contact with the substrate and the driving circuit layer providing a first via in a corresponding bending area, a flexible material layer is disposed in the first via, the planarization layer is disposed on the driving circuit layer in a direction away from the substrate, and a light-emitting functional layer is disposed on the planarization layer in a direction away from the driving circuit layer; wherein an auxiliary water-oxygen barrier layer is disposed between the light-emitting functional layer and the substrate. By providing an auxiliary water-oxygen barrier layer between the light-emitting functional layer and the substrate, water-oxygen can be isolated by the auxiliary water-oxygen barrier layer even through the gap between the second flexible layer and the second flexible layer and the second barrier layer, thus preventing erosion of the light-emitting functional layer and improving the water-oxygen isolation capacity of the OLED display panels. The technical problem that current AMOLED display panels, having a poor ability to isolate water-oxygen, is solved.

It should be noted that the flexible material layer is disposed in the first via, and the first via is not shown in FIG. 2.

In an embodiment, as shown in FIG. 2, the OLED display panel includes a display area 281 and a bending area 282. An encapsulation layer 27 is disposed on the light-emitting functional layer 26. An auxiliary water-oxygen barrier layer 22 is disposed between the substrate 21 and the flexible material layer 24. In view of the fact that water-oxygen enters through the substrate and a gap between the substrate and the driving circuit layer, and then enters the flexible material layer, the embodiment of the present application provides an auxiliary water-oxygen barrier layer disposed between the substrate and the flexible material layer. Therefore, water-oxygen can be isolated by the auxiliary water-oxygen barrier layer even through the substrate and the gap between the substrate and the driving circuit layer, thus the water-oxygen can't invade the flexible material layer, preventing erosion of the light-emitting functional layer and improving the water-oxygen isolation capacity of the OLED display panels.

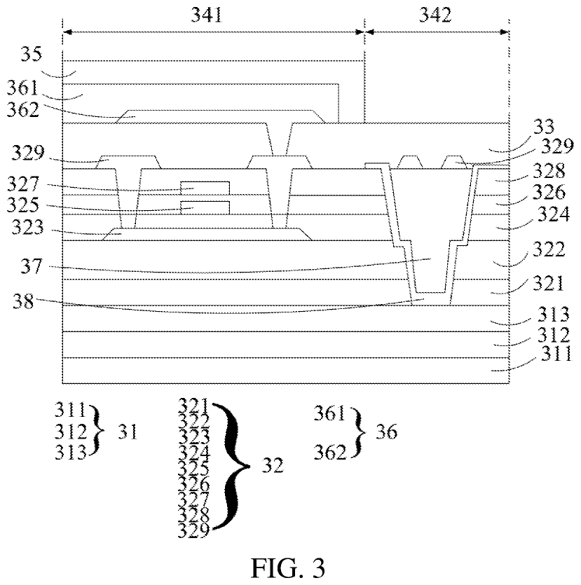

As shown in FIG. 3, an embodiment of the present application provides an OLED display panel including a substrate 31, a driving circuit layer 32, a planarization layer 33, a light-emitting functional layer 36, and an encapsulation layer 35. The substrate 31 includes a first flexible layer 311, a first barrier layer 312 and a second flexible layer 313 which are sequentially disposed. The driving circuit layer 32 includes a second barrier layer 321, a buffer layer 322, an active layer 323, a first gate insulation layer 324, a first metal layer 325, a second gate insulation layer 326, a second metal layer 327, an interlayer insulation layer 328, and a source/drain layer 329 which are sequentially disposed. The light-emitting functional layer 36 includes a pixel electrode layer 362 and a light-emitting layer 361, the light-emitting layer 361 includes a luminescent material layer, a pixel definition layer, and a common electrode layer. The OLED display panel includes a display area 341 and a bending area 342. The driving circuit layer 32 is provided with a first via, the flexible material layer 37 is disposed on the first via.

In an embodiment, as shown in FIG. 3, the auxiliary water-oxygen barrier layer 38 is disposed around the flexible material layer 37 and is provided with an opening in the flexible material layer in a direction away from the substrate. By disposing the auxiliary water-oxygen barrier layer around the flexible material layer such that water-oxygen cannot enter from a bottom surface of the flexible material layer even through the second flexible layer and a gap between the second flexible layer and the second barrier layer. And because the auxiliary water-oxygen barrier layer is disposed around the flexible material layer, water-oxygen can't be invaded from a side of the flexible material layer, thus avoiding intrusion of water-oxygen into the flexible material layer, thereby protecting the light-emitting functional layer, while avoiding erosion of the second metal layer and improving the water-oxygen isolation capacity of the OLED display panel.

In an embodiment, as shown in FIG. 3, the auxiliary water-oxygen barrier layer 38 is disposed on the bending area 342, and the auxiliary water-oxygen barrier layer 38 extends from sides of the opening to an edge of a display area of the OLED display panel and an edge of the OLED display panel. In view of further improving encapsulation performance without affecting the OLED display panel, the auxiliary water-oxygen barrier layer can be disposed to extend from sides of the opening to the edge of the display area and the edge of the OLED display panel, while improving the water-oxygen isolation capacity, the water-oxygen barrier layer will not affect a circuit in the display area, and the water-oxygen barrier layer will not increase a thickness of the OLED display panel. At the same time, considering that it is difficult to form an auxiliary water-oxygen barrier layer directly on a slope portion formed by the drive circuit layer when the auxiliary water-oxygen barrier layer is fabricated. A part of the water-oxygen barrier layer can be formed on both sides of the opening first, and then a part of the auxiliary water-oxygen barrier layer on the slope portion is formed so that the water-oxygen barrier layer is relatively easy to form.

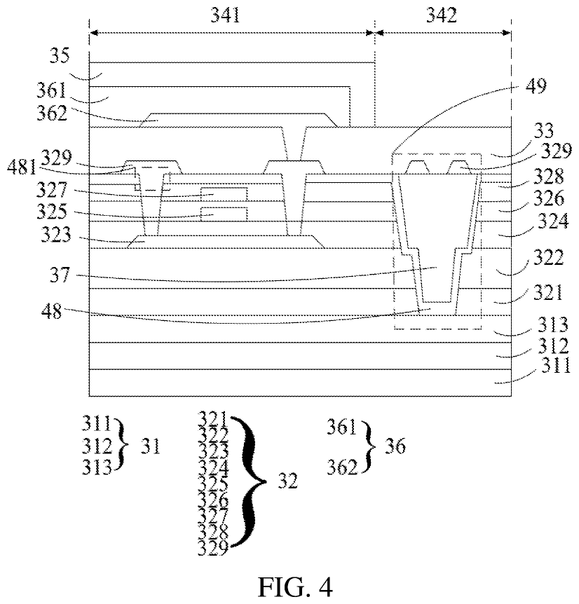

In an embodiment, as shown in FIG. 4, the flexible material layer 37 is disposed on the first via 49, and the auxiliary water-oxygen barrier layer 48 is disposed on the display area 341 and the bending area 342. The auxiliary water-oxygen barrier layer 48 extends from the opening to the edges of the OLED display panel, and the auxiliary water-oxygen barrier layer 48 is provided with a second via 481 corresponding to the display area 341, and the second via is for a source/drain electrode of the driving circuit layer to pass through. In order to further improve water-oxygen insulation capacity of the OLED display panel, the auxiliary water-oxygen barrier layer is disposed on the entire surface, so that the auxiliary water-oxygen barrier layer extends from the opening to sides of the OLED display panel. Therefore, the water-oxygen intruded from under the OLED display panel is isolated under the auxiliary water-oxygen barrier layer, thereby protecting the second metal layer and the light-emitting functional layer. And by providing a second via in the display area, the source/drain electrode in the second metal layer can be connected to the active layer through the second via, so that the driving circuit in the display area operates normally.

In an embodiment, the auxiliary water-oxygen barrier layer is disposed between the flexible material layer and the second metal layer. After the water-oxygen intrudes into the flexible material layer, the water-oxygen is isolated in the flexible layer by the auxiliary water-oxygen barrier layer disposed between the flexible material layer and the second metal layer, thereby preventing water-oxygen from intruding into the planarization layer, protecting the light-emitting functional layer, and improving the water-oxygen isolation capacity of the OLED display panel.

In an embodiment, the auxiliary water-oxygen barrier layer is disposed between the light-emitting functional layer and the planarization layer, and the auxiliary water-oxygen barrier layer is provided with a third via in an area corresponding to the display area. The third via is for the pixel electrode in the light-emitting functional layer to pass through. The auxiliary water-oxygen barrier layer can be directly disposed between the light-emitting functional layer and the planarization layer in consideration of protection of the light-emitting functional layer. Therefore, the auxiliary water-oxygen barrier layer is insulated from intruding water-oxygen, thereby protecting the light-emitting functional layer.

In an embodiment, an auxiliary water-oxygen barrier layer is disposed on the light-emitting functional layer and spans from the display area to the bending area. The auxiliary water-oxygen barrier layer is disposed between the planarization layer and the light-emitting functional layer, and extends to the bending area, so that water-oxygen cannot intrude into the light-emitting functional layer from a side of the auxiliary water-oxygen barrier layer or a gap between the water-oxygen barrier layer and the light-emitting functional layer, thereby protecting the light-emitting functional layer.

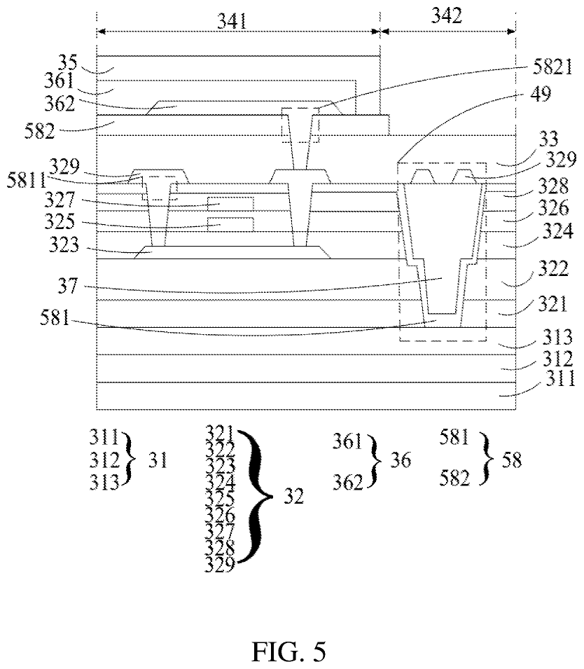

In an embodiment, as shown in FIG. 5, the auxiliary water-oxygen barrier layer 58 includes a first auxiliary water-oxygen barrier layer 581 and a second auxiliary water-oxygen barrier layer 582. The first auxiliary water-oxygen barrier layer 581 is disposed between the flexible material layer 37 and the substrate 31. The second auxiliary water-oxygen barrier layer 582 is disposed between the light-emitting functional layer 36 and the planarization layer 33 and spans to the display area 341 and the bending area 342. The second auxiliary water-oxygen barrier layer 582 is provided with a third via 5821 in the corresponding display area 341, and the third via is for a pixel electrode of the light-emitting functional layer to pass through. Considering that after the first auxiliary water-oxygen barrier layer is insulated from water-oxygen, there may be a problem of water-oxygen intrusion, and a second auxiliary water-oxygen barrier layer can be disposed between the planarization layer and the light-emitting functional layer. Therefore, the water-oxygen is again insulated by the second auxiliary water-oxygen barrier layer after being insulated by the first auxiliary water-oxygen barrier layer, so that the water-oxygen cannot intrude into the light-emitting functional layer, thereby improving the water-oxygen isolation capacity of the OLED display panel.

In an embodiment, as shown in FIG. 5, the first auxiliary water-oxygen barrier layer 581 is disposed around the flexible material layer 37, and the first auxiliary water-oxygen barrier layer 581 is disposed on the display area 341 and the bending area 342. The first auxiliary water-oxygen barrier layer 581 extends from the opening to edges of the OLED display panel, and the first auxiliary water-oxygen barrier layer 581 is provided with a fifth via 5811 in an area corresponding to the display area. The fifth via 5811 is for the source/drain electrodes of the driving circuit layer to pass through. The first auxiliary water-oxygen barrier layer can be disposed on an entire surface when the first auxiliary water-oxygen barrier layer and the second auxiliary water-oxygen barrier layer are disposed, to make the first auxiliary water-oxygen barrier layer can directly isolate the water-oxygen as much as possible under the first auxiliary water-oxygen barrier layer, and then the second auxiliary water-oxygen barrier layer only needs to isolate less water-oxygen, thereby performing protection of the light-emitting functional layer.

In the embodiment of the present application, the first auxiliary water-oxygen barrier layer is disposed on the whole surface, the first auxiliary water-oxygen barrier layer can also prevent intrusion of water-oxygen into the driving circuit after the water-oxygen passes through the flexible material layer and the water-oxygen may intrude into the driving circuit in the display area. So that the water-oxygen is isolated outside the first auxiliary water-oxygen barrier layer, or the water-oxygen is eliminated between the first water-oxygen barrier layer and the second water-oxygen barrier layer, to make the water-oxygen does not affect the individual layers of the OLED display panel.

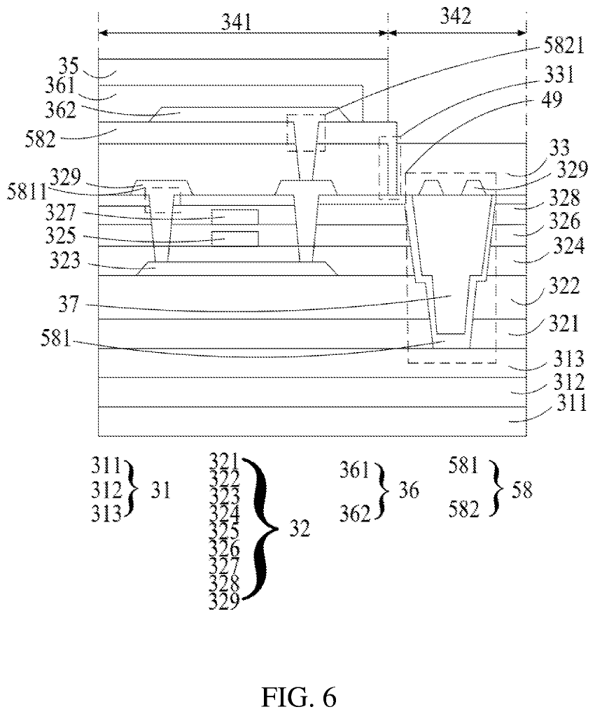

In an embodiment, as shown in FIG. 6, the planarization layer 33 is provided with a fourth via 331, the second auxiliary oxygen barrier layer 582 is connected to the first auxiliary water-oxygen barrier layer 581 through the fourth via 331. Connecting the first auxiliary water-oxygen barrier layer to the second auxiliary water-oxygen barrier layer such that the first auxiliary water-oxygen barrier layer and the second auxiliary water-oxygen barrier layer form a complete insulation layer with respect to the flexible material layer. The water-oxygen intruded from the flexible material layer must pass through the first auxiliary water-oxygen barrier layer and the second auxiliary water-oxygen barrier layer to invade. Therefore, the first auxiliary water-oxygen barrier layer and the second auxiliary water-oxygen barrier layer are insulated from the water-oxygen intruded by the flexible material layer, thereby improving the water-oxygen isolation capacity of the OLED display panel.

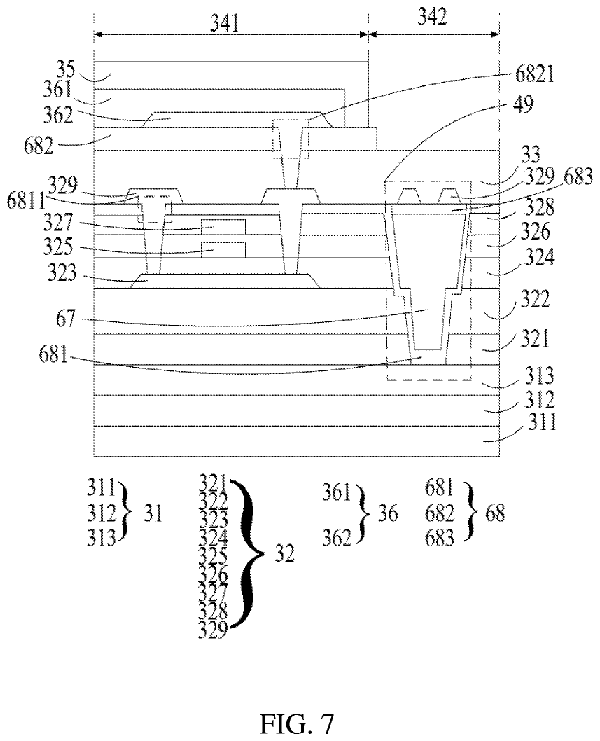

In an embodiment, as shown in FIG. 7, the auxiliary water-oxygen barrier layer 68 includes a first auxiliary water-oxygen barrier layer 681, a second auxiliary water-oxygen barrier layer 682, and a third auxiliary water-oxygen barrier layer 683. The third auxiliary water-oxygen barrier layer 683 is disposed between the flexible material layer 67 and the second metal layer 329 of the driving circuit layer, and the third auxiliary water-oxygen barrier layer 683 is connected to the first auxiliary water-oxygen barrier layer 681. Considering that water-oxygen may pass through the first auxiliary water-oxygen barrier layer into the flexible material layer, a third auxiliary water-oxygen barrier layer can be disposed between the flexible material layer and the second metal layer, and the third auxiliary water-oxygen barrier layer is connected to the first auxiliary water-oxygen barrier layer. Therefore, the water-oxygen is blocked by the third auxiliary water-oxygen barrier layer after passing through the flexible material layer, thereby preventing water-oxygen from entering the planarization layer. Furthermore, the second auxiliary water-oxygen barrier layer is disposed between the planarization layer and the light-emitting functional layer. Even if the water-oxygen passes through the planarization layer, it will be insulated by the second auxiliary water-oxygen barrier layer, thereby isolating the water-oxygen from intruding into the light-emitting functional layer, that is, by providing three times of isolating water-oxygen to protect the light-emitting functional layer, and improving the water-oxygen isolation capacity of the OLED display panel.

In an embodiment, the material of the auxiliary water-oxygen barrier layer is an inorganic material, and the inorganic material is used to insulate water-oxygen to avoid intrusion of water-oxygen on the OLED display panel. The inorganic material can be a material that is strong in isolation of water-oxygen, such as silicon oxide, silicon nitride, or silicon oxynitride. The auxiliary water-oxygen barrier layer can also be a dense material, for example, a compact material is formed by compression, thereby forming a dense film layer to achieve a better effect on the isolation of water-oxygen.

In an embodiment, the driving circuit layer includes a buffer layer and a first gate insulation layer. A step of the flexible material layer is provided at an interface corresponding to the first gate insulation layer and the buffer layer, and sides of the auxiliary water-oxygen barrier layer extend to the step. Since the flexible material layer is formed with the step at the interface between the first gate insulation layer and the buffer layer, when the auxiliary water-oxygen barrier layer is disposed, the auxiliary water-oxygen layer is disposed mainly between the substrate and the flexible material layer, and then the auxiliary water-oxygen barrier layer is extended to the steps. It is avoided that when the auxiliary water-oxygen barrier layer is disposed only between the substrate and the flexible material layer, the water-oxygen enters the flexible material layer from the gap between the auxiliary water-oxygen barrier layer and the flexible material layer, and the auxiliary water-oxygen barrier layer is small, which does not affect the flexibility of the bending area. In the formation of the auxiliary water-oxygen barrier layer, a portion of the auxiliary water-oxygen barrier layer can be formed at the step, and then a slope portion and a bottom portion are formed, thereby forming an auxiliary water-oxygen barrier layer. Therefore, the auxiliary water-oxygen barrier layer is relatively easy to form.

In an embodiment, the auxiliary water-oxygen barrier layer is disposed between the substrate and the flexible material layer, and the auxiliary water-oxygen barrier layer extends from sides to the second gate insulation layer.

In an embodiment, the auxiliary water-oxygen barrier layer is disposed between the substrate and the flexible material layer, and the auxiliary water-oxygen barrier layer extends from sides to the interlayer insulation layer.

In an embodiment, the driving circuit layer is provided with a first via, the flexible material layer is disposed in the first via, and the flexible material layer includes a first flexible material layer and a second flexible material layer. The second flexible material layer is disposed on the first flexible material layer in a direction away from the substrate. The auxiliary water-oxygen barrier layer is disposed between the first flexible material layer and the second flexible material layer. For the water-oxygen intrusion into the flexible material layer, an auxiliary water-oxygen barrier layer can be disposed between the flexible material layers, so that after the water-oxygen intrudes the first flexible material layer, the water-oxygen is isolated by the auxiliary water-oxygen barrier layer and cannot enter the second flexible material layer, which prevents water-oxygen from intruding into the planarization layer.

In an embodiment, an auxiliary water-oxygen barrier layer can be formed between the first flexible material layer and the substrate, an auxiliary water-oxygen barrier layer can be formed between the first flexible material layer and the second flexible material layer, and an auxiliary water-oxygen barrier layer is formed between the flexible material layer and the second metal layer. Therefore, the water-oxygen needs to pass through the auxiliary pattern insulation layer three times, the auxiliary water-oxygen barrier layer isolates the water-oxygen under the planarization layer to prevent the water-oxygen from entering the planarization layer, which protects the light-emitting functional layer and improves the water-oxygen isolation capacity of the OLED display panel.

In an embodiment, in order not to affect the flexibility of the OLED display panel, the auxiliary water-oxygen barrier layer can be made thinner, or by increasing a ratio of thickness of the flexible material layer to the auxiliary water-oxygen barrier layer, such as the ratio of thickness of the flexible material layer and thickness of the auxiliary water-oxygen barrier layer is 20:1, so as to minimize the influence on the flexibility of the OLED display panel. The actual data select the thickness of the auxiliary water-oxygen barrier layer by increasing the water-oxygen isolation capacity of the OLED display panel and not affecting the flexibility of the OLED display panel, and without increasing the thickness of the OLED display panel.

In an embodiment, the auxiliary water-oxygen barrier layer is disposed on any one of the buffer layer, the first gate insulation layer, the second gate insulation layer, and the interlayer insulation layer.

An embodiment of the present application provides an OLED display device. The OLED display device includes an OLED display panel, and the OLED display panel includes:

a substrate;

a driving circuit layer disposed in close contact with the substrate, the driving circuit layer includes a first via corresponding to a bending area of the driving circuit layer and a flexible material layer provided in the first via;

a planarization layer disposed on the driving circuit layer in a direction away from the substrate; and

a light-emitting functional layer disposed on the planarization layer in a direction away from the driving circuit layer;

wherein an auxiliary water-oxygen barrier layer is disposed between the light-emitting functional layer and the substrate.

An embodiment of the present application provides an OLED display device including an OLED display panel, the OLED display panel including a substrate, a driving circuit layer, a planarization layer, and a light-emitting functional layer, wherein the driving circuit layer is disposed in close contact with the substrate and the driving circuit layer providing a first via in a corresponding bending area, a flexible material layer is disposed in the first via, the planarization layer is disposed on the driving circuit layer in a direction away from the substrate, and a light-emitting functional layer is disposed on the planarization layer in a direction away from the driving circuit layer; wherein an auxiliary water-oxygen barrier layer is disposed between the light-emitting functional layer and the substrate. By providing an auxiliary water-oxygen barrier layer between the light-emitting functional layer and the substrate, water-oxygen can be isolated by the auxiliary water-oxygen barrier layer even through the second barrier layer and the gap between the second flexible layer and the second flexible layer, thus preventing erosion of the light-emitting functional layer and improving the water-oxygen isolation capacity of the OLED display panels. The technical problem that current AMOLED display panels, having a poor ability to isolate water-oxygen, is solved.

In an embodiment, the auxiliary water-oxygen barrier layer is disposed between the substrate and the flexible material layer.

In an embodiment, the auxiliary water-oxygen barrier layer is disposed around the flexible material layer and is provided with an opening in the flexible material layer in a direction away from the substrate.

In an embodiment, the auxiliary water-oxygen barrier layer is disposed on the bending area, and the auxiliary water-oxygen barrier layer extends from both sides of the opening to the edge of the display area and the edge of the OLED display panel.

In an embodiment, the auxiliary water-oxygen barrier layer is disposed on the display area and the bending area, and the auxiliary water-oxygen barrier layer extends from sides of the opening to the edges of the OLED display panel. The auxiliary water-oxygen barrier layer is provided with a second via corresponding to the display area, and the second via is for the source/drain electrode of the driving circuit layer to pass through.

In an embodiment, the driving circuit layer includes a buffer layer and a first gate insulation layer, the flexible material layer provided with a step at an interface corresponding to the first gate insulation layer and the buffer layer. The auxiliary water-oxygen barrier layer extends to the step.

In an embodiment, the auxiliary water-oxygen barrier layer includes a first auxiliary water-oxygen barrier layer and a second auxiliary water-oxygen barrier layer. The first auxiliary water-oxygen barrier layer is disposed between the flexible material layer and the substrate. The second auxiliary water-oxygen barrier layer is disposed between the light-emitting functional layer and the planarization layer and spans to the display area and the bending area, and the second auxiliary water-oxygen barrier layer is provided with a third via in the corresponding display area, and the third via is for a pixel electrode of the light-emitting functional layer to pass through.

In an embodiment, the planarization layer is provided with a fourth via, and the second auxiliary water-oxygen barrier layer is connected to the first auxiliary water-oxygen barrier layer through the fourth via.

In an embodiment, the auxiliary water-oxygen barrier layer further includes a third auxiliary water-oxygen barrier layer, the third auxiliary water-oxygen barrier layer is disposed between the flexible material layer and the second metal layer of the driving circuit layer, and the third auxiliary water-oxygen barrier layer is connected to the first auxiliary water-oxygen barrier layer.

In an embodiment, material of the auxiliary water-oxygen barrier layer is at least one of silicon oxide, silicon nitride, and silicon oxynitride.

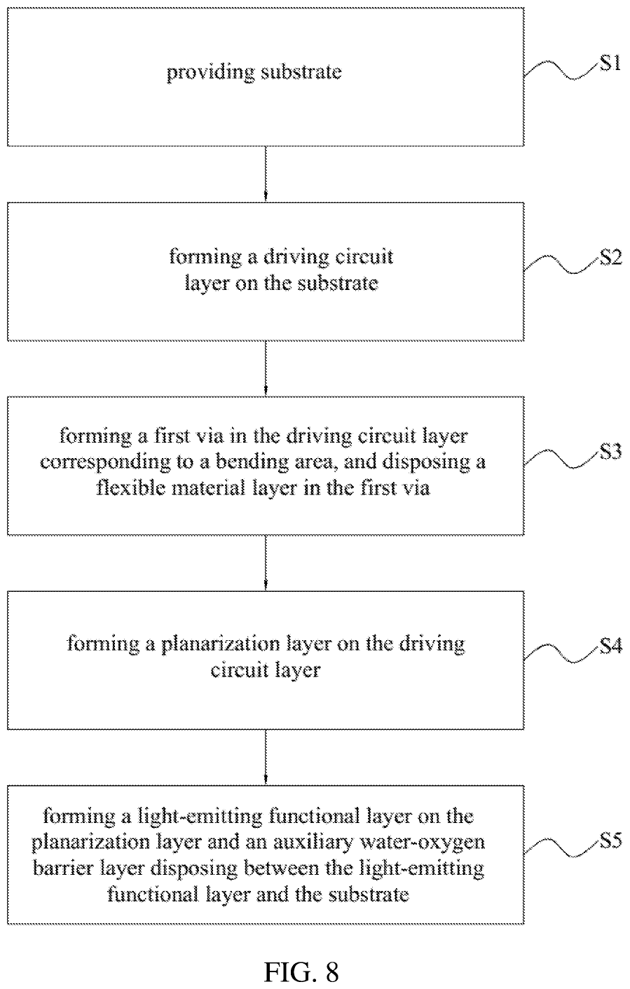

As shown in FIG. 8, an embodiment of the present application provides a method for fabricating an OLED display panel, and the method for fabricating the OLED display panel includes:

S1, providing a substrate;

S2, forming a driving circuit layer on the substrate;

S3, forming a first via in the driving circuit layer corresponding to a bending area, and disposing a flexible material layer in the first via;

S4, forming a planarization layer on the driving circuit layer;

S5, forming a light-emitting functional layer on the planarization layer and an auxiliary water-oxygen barrier layer disposing between the light-emitting functional layer and the substrate.

An embodiment of the present application provides a method for fabricating an OLED display panel. The OLED display panel fabricated by the OLED display panel manufacturing method includes a substrate, a driving circuit layer, a planarization layer, and a light-emitting functional layer, wherein the driving circuit layer is disposed in close contact with the substrate and the driving circuit layer providing a first via in a corresponding bending area, a flexible material layer is disposed in the first via, the planarization layer is disposed on the driving circuit layer in a direction away from the substrate, and a light-emitting functional layer is disposed on the planarization layer in a direction away from the driving circuit layer; wherein an auxiliary water-oxygen barrier layer is disposed between the light-emitting functional layer and the substrate. By providing an auxiliary water-oxygen barrier layer between the light-emitting functional layer and the substrate, water-oxygen can be isolated by the auxiliary water-oxygen barrier layer even through the gap between the second flexible layer and the second flexible layer and the second barrier layer, thus preventing erosion of the light-emitting functional layer and improving the water-oxygen isolation capacity of the OLED display panels. The technical problem that current AMOLED display panels, having a poor ability to isolate water-oxygen, is solved.

According to the above embodiments, it can be known that:

Embodiments of the present application provide an OLED display panel, a method for fabricating the same, and an OLED display device. The OLED display panel including a substrate, a driving circuit layer, a planarization layer, and a light-emitting functional layer, wherein the driving circuit layer is disposed in close contact with the substrate and the driving circuit layer providing a first via in a corresponding bending area, a flexible material layer is disposed in the first via, the planarization layer is disposed on the driving circuit layer in a direction away from the substrate, and a light-emitting functional layer is disposed on the planarization layer in a direction away from the driving circuit layer; wherein an auxiliary water-oxygen barrier layer is disposed between the light-emitting functional layer and the substrate. By providing an auxiliary water-oxygen barrier layer between the light-emitting functional layer and the substrate, water-oxygen can be isolated by the auxiliary water-oxygen barrier layer even through the gap between the second flexible layer and the second flexible layer and the second barrier layer, thus preventing erosion of the light-emitting functional layer and improving the water-oxygen isolation capacity of the OLED display panels. The technical problem that current AMOLED display panels, having a poor ability to isolate water-oxygen, is solved.

Embodiments of the present invention have been described, but not intending to impose any unduly constraint to the appended claims. For a person skilled in the art, any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. An organic light-emitting diode (OLED) display panel, comprising:
a substrate;
a driving circuit layer disposed in close contact with the substrate, the driving circuit layer comprises a first via corresponding to a bending area of the driving circuit layer, and a flexible material layer provided in the first via;
a planarization layer disposed on the driving circuit layer in a direction away from the substrate;
a light-emitting functional layer disposed on the planarization layer in a direction away from the driving circuit layer; and
an auxiliary water-oxygen barrier layer disposed between the light-emitting functional layer and the substrate.

2. The OLED display panel of claim 1, wherein the auxiliary water-oxygen barrier layer is disposed between the substrate and the flexible material layer.

3. The OLED display panel of claim 2, wherein the auxiliary water-oxygen barrier layer is disposed around the flexible material layer and is provided with an opening in the flexible material layer in a direction away from the substrate.

4. The OLED display panel of claim 3, wherein the auxiliary water-oxygen barrier layer is disposed in the bending area, and the auxiliary water-oxygen barrier layer extends from sides of the opening to an edge of a display area of the OLED display panel and an edge of the OLED display panel.

5. The OLED display panel of claim 4, wherein the auxiliary water-oxygen barrier layer is disposed on the display area and the bending area, and the auxiliary water-oxygen barrier layer extends from sides of the opening to the edge of the display area and the edge of the OLED display panel, the auxiliary water-oxygen barrier layer is provided with a second via corresponding to the display area, and the second via is for a source/drain electrode of the driving circuit layer to pass through.

6. The OLED display panel of claim 2, wherein the driving circuit layer comprises a buffer layer and a first gate insulation layer, a step of the flexible material layer is provided at an interface corresponding to the first gate insulation layer and the buffer layer, and sides of the auxiliary water-oxygen barrier layer extend to the step.

7. The OLED display panel of claim 1, wherein the auxiliary water-oxygen barrier layer comprises a first auxiliary water-oxygen barrier layer and a second auxiliary water-oxygen barrier layer, the first auxiliary water-oxygen barrier layer is disposed between the flexible material layer and the substrate, the second auxiliary water-oxygen barrier layer is disposed between the light-emitting functional layer and the planarization layer and spans from the display area to the bending area, and the second auxiliary water-oxygen barrier layer is provided with a third via in the corresponding display area, and the third via is for a pixel electrode of the light-emitting functional layer to pass through.

8. The OLED display panel of claim 7, wherein the planarization layer is provided with a fourth via, the second auxiliary water-oxygen barrier layer is connected to the fourth via through the first auxiliary water-oxygen barrier layer.

9. The OLED display panel of claim 7, wherein the auxiliary water-oxygen barrier layer further comprises a third auxiliary water-oxygen barrier layer, the third auxiliary water-oxygen barrier layer is disposed between the flexible material layer and a second metal layers of the driving circuit layer, and the third auxiliary water-oxygen barrier layer is connected to the first auxiliary water-oxygen barrier layer.

10. The OLED display panel of claim 1, wherein the auxiliary water-oxygen barrier layer is made of at least one of silicon oxide, silicon nitride, and silicon oxynitride.

11. An organic light-emitting diode (OLED) display device comprising an OLED display panel, the OLED display panel comprising:
a substrate;
a driving circuit layer disposed in close contact with the substrate, the driving circuit layer comprises a first via corresponding to a bending area of the driving circuit layer, and a flexible material layer provided in the first via;
a planarization layer disposed on the driving circuit layer in a direction away from the substrate;
a light-emitting functional layer disposed on the planarization layer in a direction away from the driving circuit layer; and
an auxiliary water-oxygen barrier layer disposed between the light-emitting functional layer and the substrate.

12. The OLED display device of claim 11, wherein the auxiliary water-oxygen barrier layer is disposed between the substrate and the flexible material layer.

13. The OLED display device of claim 12, wherein the auxiliary water-oxygen barrier layer is disposed around the flexible material layer and is provided with an opening in the flexible material layer in a direction away from the substrate.

14. The OLED display device of claim 13, wherein the auxiliary water-oxygen barrier layer is disposed in the bending area, and the auxiliary water-oxygen barrier layer extends from sides of the opening to an edge of a display area of the OLED display panel and an edge of the OLED display panel.

15. The OLED display device of claim 14, wherein the auxiliary water-oxygen barrier layer is disposed on the display area and the bending area, and the auxiliary water-oxygen barrier layer extends from sides of the opening to the edge of the display area and the edge of the OLED display panel, the auxiliary water-oxygen barrier layer is provided with a second via corresponding to the display area, and the second via is for a source/drain electrode of the driving circuit layer to pass through.

16. The OLED display device of claim 12, wherein the driving circuit layer comprises a buffer layer and a first gate insulation layer, a step of the flexible material layer is provided at an interface corresponding to the first gate insulation layer and the buffer layer, and sides of the auxiliary water-oxygen barrier layer extend to the step.

17. The OLED display device of claim 11, wherein the auxiliary water-oxygen barrier layer comprises a first auxiliary water-oxygen barrier layer and a second auxiliary water-oxygen barrier layer, the first auxiliary water-oxygen barrier layer is disposed between the flexible material layer and the substrate, the second auxiliary water-oxygen barrier layer is disposed between the light-emitting functional layer and the planarization layer and spans from the display area to the bending area, and the second auxiliary water-oxygen barrier layer is provided with a third via in the corresponding display area, and the third via is for a pixel electrode of the light-emitting functional layer to pass through.

18. The OLED display device of claim 17, wherein the planarization layer is provided with a fourth via, the second auxiliary water-oxygen barrier layer is connected to the fourth via through the first auxiliary water-oxygen barrier layer.

19. The OLED display device of claim 17, wherein the auxiliary water-oxygen barrier layer further comprises a third auxiliary water-oxygen barrier layer, the third auxiliary water-oxygen barrier layer is disposed between the flexible material layer and a second metal layers of the driving circuit layer, and the third auxiliary water-oxygen barrier layer is connected to the first auxiliary water-oxygen barrier layer.

20. The OLED display device of claim 11, wherein the auxiliary water-oxygen barrier layer is made of at least one of silicon oxide, silicon nitride, and silicon oxynitride.
